(19) United States
(12) Patent Application Publication
(10) Pub. No.: US 2023/0357633 A1
(43) Pub. Date: Nov. 9, 2023

(54) PHOSPHOR MIXTURE FOR USE IN A CONVERSION LAYER ON A SEMICONDUCTOR LIGHT SOURCE

(71) Applicant: OSRAM GmbH, Munich (DE)

(72) Inventors: Michael SCHOEWEL, Moosthenning (DE); Stefan SCHWEDHELM, Ulm (DE)

(21) Appl. No.: 18/246,876

(22) PCT Filed: Aug. 5, 2021
(86) PCT No.: PCT/EP2021/071924

§ 371 Date: Mar. 28, 2023

(30) Foreign Application Priority Data
Sep. 28, 2020 (DE) 10 2020 212 154.0

(51) Int. Cl. C09K 11/77; C09K 11/02; H01L 33/50; F21S 43/16

(52) U.S. Cl. CPC C09K 11/77348; C09K 11/02; H01L 33/502; F21S 43/16

(57) ABSTRACT

A phosphor composition may include first and second phosphors configured to emit light of a first and a second unsaturated color, respectively. The first unsaturated color may be associated with a first position in a CIE standard color chart adjacent to and above a position of a selected target color of the phosphor composition in the CIE standard color chart. The second unsaturated color may be associated with a second position in a CIE chromaticity diagram adjacent to and below the position of the selected target color of the phosphor composition in the CIE chromaticity diagram. Thereby, the position of the selected target color of the phosphor composition in the CIE chromaticity diagram may be located in an area defined by corner positions R=(cx; cy) given by R1=(0.645; 0.335), R2=(0.665; 0.335), R3=(0.735; 0.265), and R4=(0.721; 0.259).

### CROSS-REFERENCE TO RELATED APPLICATIONS

The present application is a national stage entry according to 35 U.S.C. § 371 of PCT application No.: PCT/EP2021/071924 filed on Aug. 5, 2021; which claims priority to German patent application DE 10 2020 212 154.0, filed on Sep. 28, 2020; all of which are incorporated herein by reference in their entirety and for all purposes.

### TECHNICAL FIELD

Various embodiments relate to a phosphor mixture for use in a conversion layer coated on a semiconductor light source.

### BACKGROUND

In motor vehicles, lamps with semiconductor light sources or LEDs (light-emitting diodes) are increasingly being used as illuminants. They offer advantages such as cost savings, greater flexibility with regard to the color temperatures that can be displayed, durability and, above all, energy savings, etc. compared with conventional halogen lamps or gas discharge lamps. In addition, they can also be used very efficiently to display the color ranges defined in Europe, for example, by ECE regulations, which are bindingly assigned to certain lighting and light signaling devices on motor vehicles, such as red for brake lighting or yellow for the lane change blinker (turn signal), etc. The ECE regulations are laid down in the Agreement concerning the Adoption of Uniform Conditions of Approval and Reciprocal Recognition of Approval for Motor Vehicle Equipment and Parts of 20 Mar. 1958, initiated by the United Nations Economic Commission for Europe (UN/ECE for short), and declared mandatory in Europe in Annex IV of Regulation (EC) No. 661/2009. Relevant in relation to vehicle lighting is Regulation 48 “Installation of lighting and light-signaling devices on motor vehicles”.

A large number of material systems (semiconductors) are available for LEDs, which show emission at wavelengths distributed over the visible spectral range as well as beyond (IR, UV) according to the respective band gaps. In the simplest case, an LED emitting just in the corresponding wavelength range could be selected to achieve a red hue mandatory for brake lights, tail lights or rear fog lights, i.e., via a direct emitter. Here, for example, gallium arsenide phosphide with a suitable mixing ratio between gallium arsenide and gallium phosphide could be considered. Direct emitters provide a highly saturated color, i.e., a color close to the outer spectral color line in a CIE standard chromaticity diagram. However, the problem here is that in the red wavelength range, direct emitters are relatively ineffective from a thermal point of view, so that their suitability as vehicle lamps is limited.

In order to be able to display a certain specified color via LEDs, an alternative approach is to use phosphors that are applied to the respective semiconductor light source of the LED. The phosphor is present here in a conversion layer. The underlying semiconductor light source emits light of a comparatively shorter wavelength, e.g. in the blue-visual or UV range, and the applied phosphor absorbs this emission in whole or in part and in turn emits a portion of the absorbed energy in a longer wavelength range, e.g. to emit yellow, orange, garnet or red to deep red light.

Depending on which part of the original short-wave light of the semiconductor light source is absorbed and is therefore no longer available for the light finally emitted from the LED, the saturation of the resulting color tone is determined accordingly. This is because the color locus in the CIE standard chromaticity diagram results from a synopsis of the color loci of the light emitted by the semiconductor light source and the light absorbed by the phosphor and re-emitted in the long-wave range. Depending on the proportion or ratio of the light emitted by the semiconductor light source and transmitted through the conversion layer with the phosphor to the light re-emitted by the phosphor, the resulting color locus in the CIE standard color chart lies on a line between the two color loci of the semiconductor light source and the phosphor, in any case in a rather unsaturated range of colors. Only towards a full conversion of the light by the phosphor does the chromaticity coordinate approach the outer spectral color line in the CIE standard chromaticity diagram. Since the reemission is generally not so narrow-banded, depending on the dye, however, even in this case there is regularly no complete saturation.

For example, unsaturated “garnet-colored” phosphors are available for the representation of red light, as in the case of brake lights, tail lights and rear fog lights, which are indeed “bright”, i.e. show a high luminous efficacy, even if the convolution of the emitted spectrum with a sensitivity curve of the human eye is taken into account, which namely already drops sharply at wavelengths above 650 nm. However, such dyes usually have a comparatively low saturation, so that they achieve an ECE-compliant window in the CIE standard chromaticity diagram for red light (close to the spectral color line) only if a high degree of conversion of the emitted light is achieved. However, a higher conversion is only accompanied by a greater thickness of the conversion layer or a greater encapsulation height of the phosphor, so that in turn the luminous flux that can then be achieved is negatively affected. In addition, the color locus—even if it lies within the permissible window—is in the garnet range, while a deeper red is desirable.

On the other hand, there are also unsaturated “red” phosphors available whose degree of saturation is at least comparatively improved and whose chromaticity coordinates are also comparatively optimized in the deeper red color range. However, the sensitivity curve of the human eye, which drops in the deep red range, becomes very noticeable here.

The color locations depend as described on the selected phosphor and on the encapsulation height or layer thickness of the conversion layer (can also be determined via the so-called dispensing weight per area of the semiconductor light sources on which sedimentation or application is carried out), whereby the corresponding value in the CIE standard chromaticity diagram can be changed in the cx direction (in the direction of the red component). However, the color location of the phosphor also depends on the temperature, or on temperature-influencing factors such as current for operating the semiconductor light source or the method of cooling the LED chip, whereby here in particular there is also a variation in the cy direction (in the direction of the green component) of the CIE standard chromaticity diagram.

In the case of unsaturated dyes, a process-related scattering of the dispensing weight now has a major influence on the color locus and thus also, eye-weighted, on the luminous flux generated photometrically from it. Furthermore, temperature changes during operation also affect the color locus. In the case of the aforementioned red phosphors with high eye sensitivity, such fluctuations can have a significant effect on the resulting luminous flux, which must be avoided.

In the case of dispersion of the dispensing weight (i.e., the weight of the deposited or applied phosphor), an increase of the same can still remedy the situation, with advantage as described a degree of saturation is improved, but at the same time the luminous flux as a whole drops to a considerable extent due to increased absorption, i.e., multiple absorption, with disadvantage. In addition, the dispensing process takes much longer, which increases the cost of mass production of what are in themselves inexpensive products. Consequently, the result remains that in the case of deep red phosphors, despite useful color locations, unavoidable scattering in the dispensing weight during production and unavoidable temperature fluctuations result in changes in the luminous flux that are difficult to accept.

A measure known to the inventors to remedy the problem nevertheless consists of using the electronic control system to compensate for a fluctuation in the luminous flux detected by direct or indirect measurement by increasing the lamp current. It should be noted that this in turn can change the temperature again and also change the color location, which may not be compensatable.

It is also known to the inventors to mix two or more phosphors in a conversion layer, e.g. to bridge band gaps or wavelength ranges.

### SUMMARY

In order to offer a solution to these or similar problems, the following aspects and embodiments are intended to improve color saturation and at the same time stabilize the luminous flux against operational and/or process-related influences for LED lamps to be used in particular in vehicles, which emit light in an ECE-compliant window of the CIE chromaticity diagram for red light.

According to one embodiment, a phosphor mixture is provided for use in a conversion layer coated on a semiconductor light source. The phosphor mixture comprises a first phosphor adapted to emit light of a first unsaturated color when irradiated with light from the semiconductor light source and would be provided as the only phosphor in the conversion layer, wherein the first unsaturated color is associated with a first position in a CIE chromaticity diagram that is adjacent to and above a position of a selected target color of the phosphor composition in the CIE chromaticity diagram.

Further, the phosphor composition comprises a second phosphor adapted to emit light of a second unsaturated color when irradiated with light from the semiconductor light source and would be the only phosphor provided in the conversion layer, the second unsaturated color being associated with a second position in the CIE chromaticity diagram that is adjacent to and below the position of the selected target color of the phosphor composition in the CIE chromaticity diagram.

In this case, the position of the selected target color of the phosphor composition in the CIE chromaticity diagram is located in an area defined by corner positions R=(cx; cy) given by
R1=(0,645; 0,335),
R2=(0,665; 0,335),
R3=(0.735; 0.265), and
R4=(0,721; 0,259).

The area defined by the corner positions in the CIE Standard Color Chart corresponds to red light as provided for brake lights, tail lights, rear fog lights, etc., in accordance with Regulation 48 of the UN/ECE, as last amended by the 5th series of amendments on Jan. 30, 2011, Official Journal of the European Union I. 323/46 of Dec. 6, 2011. The CIE standard chromaticity diagram (also known as the CIE standard valence system) is given, for example, in “Colorimetry—Part 1: CIE Standard Colorimetric Observers”, 2nd Edition, Joint ISO/CIE Standard, ISO 11664-1:2007(E)/CIE S 014-1/E:2006, CIE (2006), Vienna: Central Bureau of the Commission Internationale de I′ Éclairage in tabular form or by functions. The coordinate cx denotes the proportion of light from a source of the primary color red (700 nm), and the coordinate cy denotes the proportion of light from a source of the primary color green (546.1 nm). The third coordinate cz, which is regularly not shown separately, designates the proportion of light of the primary color blue (435.8 nm). The values lie in each case between 0 and 1 and add up to 1. The proportion cz is defined by the sum of the proportions cx and cy.

In the following (and also in the preceding), the term “chromaticity coordinate” is used to express a position in the CIE chromaticity diagram.

According to the embodiment example, it is consequently proposed to mix two phosphors which differ with regard to their color location in the CIE standard chromaticity diagram in the cy direction and are located above and below the selected target color location of the phosphor mixture, i.e. on either side of it in the cy direction. The positions of the first and second unsaturated colors of the two phosphors may, but need not, be within the color frame for the ECE-compliant red defined by the corner positions.

Surprisingly, it was found that the combination of the two phosphors produces a phosphor mixture whose emitted light achieves higher color saturation than either of the phosphors individually. With a simple addition of the light contributions, a resulting chromaticity coordinate would have been expected along a connecting line between the chromaticity coordinates of the individual phosphors, so that an improvement in saturation, represented by a distance of the chromaticity coordinate from the nearest spectral color at the edge of the chromaticity diagram, could not actually result for geometric reasons alone. However, the investigations carried out here clearly show that the chromaticity coordinate obtained by mixing is significantly shifted to higher values in the cx direction compared to such a connecting line.

In particular, it was found that the second phosphor, whose second unsaturated color has a position in the CIE chromaticity diagram below the selected target color and thus further into the deep red to purple range, provides a kind of filter band or bandpass for the first phosphor. The emission spectra of the two phosphors are so close to each other, and overlap to such an extent, that only a narrow region on the short-wave flank of the emission spectrum of the first phosphor is not covered by the emission spectrum of the second phosphor. Because the second phosphor can at least partially absorb light on the short-distance side where it does not emit light, it also contributes to the absorption in this wavelength range of the light emitted by the first phosphor. The second phosphor in turn emits the corresponding absorbed energy in its own emission spectrum. Since the composite emission spectrum is limited on the boring side by the sensitivity curve of the human eye (with which it is to be folded), it becomes narrower and more pronounced in interaction by the filtering on the short-wave side. This is then directly reflected in a higher saturation in the CIE standard chromaticity diagram.

A particular advantage arises from the fact that the stability of the luminous flux provided by the first phosphor, whose first unsaturated color has a position in the CIE standard chromaticity diagram above the target chromaticity point and thus lies more in the garnet or orange range, is maintained or even improved by the mixture in the face of fluctuations, particularly in temperature. In this respect, there was rather a weak point with regard to the second phosphor, because it is even more limited by the sensitivity curve of the human eye, so that fluctuations can lead to a considerable change in the luminous flux. However, if this is the case in the mixture, the first phosphor cushions such massive changes in luminous flux, while the second phosphor still retains its filter function.

Furthermore, it is possible to precisely define the target color location in the mixture via the mixing ratio, both in the cx direction and in the cy direction. For this purpose, it is not necessary to intervene in the hardware (e.g. cooling) or software (current control). As a result, cost savings are also possible.

Furthermore, test results show that a sensitivity of the target color locus of the phosphor mixture to scattering and fluctuations (dispensing weight, temperature) is also more stable in both the cx-direction and cy-direction compared to the corresponding sensitivity of the color locus for the first and second phosphors, respectively.

It was also found that an optimum, lower sensitivity of the target color location of the phosphor mixture is already possible at lower dispensing weights (backfill heights or thicknesses of the conversion layers) compared to the situation with the individual phosphors. As a result, material savings are also possible.

According to a further embodiment, the phosphor mixture is adapted to emit light of the selected target color associated with the position in the CIE chromaticity diagram when irradiated with light from the semiconductor light source and provided in the conversion layer, said position having a degree of saturation represented by a distance from the nearest spectral color which is greater than a corresponding degree of saturation of said first unsaturated color or said second unsaturated color or both said first unsaturated color and said second unsaturated color.

These features further specify the advantages of higher color location stability and luminous flux, as well as material and cost savings.

According to another further embodiment of the phosphor mixture, the first phosphor, when irradiated with light by the semiconductor light source, is adapted to emit light having a first spectrum exhibiting light emission in a first wavelength range. Further, also the second phosphor is adapted, when irradiated with light by the semiconductor light source, to emit light having a second spectrum exhibiting light emission in a second wavelength range. The first wavelength range overlaps the second wavelength range at least in an interval between 600 nm and 700 nm.

In this case, there is a large overlap range at wavelengths of red light, so that the filter effect mentioned above becomes particularly effective due to the second phosphor. As a result, particularly good saturation values can be achieved for the target color.

According to another further embodiment of the phosphor mixture, maximum values of the first and second spectra are at wavelengths within the wavelength interval between 600 nm and 700 nm.

These features result in an even denser overlap area, so that the filtering effect mentioned above is even stronger due to the second phosphor.

According to another further embodiment of the phosphor mixture, the second phosphor is adapted to absorb and filter light in a region of the first wavelength range that extends adjacent to the lower boundary thereof.

Since in this way the second phosphor absorbs a short-duration portion of the emission spectrum of the first phosphor and itself emits in its more boring wavelength range, the filter function is improved, and a higher degree of saturation is achieved.

According to another further embodiment of the phosphor mixture, the second phosphor is adapted to absorb and filter light in a region of the first wavelength range between 500 and 580 nm.

These features result in a shift of the target color locus or position of the target color in the CIE chromaticity diagram to deeper reds (cx and cy greater) at higher saturation levels.

According to a further embodiment of the phosphor mixture, the semiconductor light source is adapted to emit blue light. In other words, the phosphor mixture is designed to absorb blue light from a semiconductor light source in order to emit it in the red spectral range. With this combination, particularly good results are achieved in terms of color saturation and color stability.

Particularly good results are achieved when the semiconductor light source is designed to emit light in a wavelength range between 447.5 nm and 450 nm.

According to a further embodiment of the phosphor mixture, a thickness of the phosphor mixture can be 30 μm to 70 μm, whereby a median value of the particle size D50 in the phosphor mixture can be between 5 μm and 20 μm. For these values, particularly good results were obtained in terms of saturation and color location stability.

According to another further development of the embodiment of the phosphor mixture, the second phosphor, when provided as a single phosphor in a conversion layer and irradiated by the semiconductor light source, is adapted to emit light of a second unsaturated color associated with a position in a CIE standard chromaticity diagram having a basic color component of green of cy≤0.324. In this case, the second phosphor develops a particularly efficient filtering effect compared to the first phosphor.

According to another further embodiment of the phosphor mixture, the first phosphor, when provided as a single phosphor in a conversion layer and irradiated by the semiconductor light source, is adapted to emit light of a first unsaturated color associated with a position in a CIE standard chromaticity diagram having a basic chromaticity coordinates of green of cy≥0.328. In this case, the first phosphor may be particularly effective in being subject to the filtering effect by the second phosphor.

According to a further embodiment, the phosphor mixture, when irradiated by the semiconductor light source, is adapted to emit light of the selected target color associated with a position in the CIE chromaticity diagram corresponding to a degree of saturation represented by a distance≤0.012 in the cx direction from the nearest spectral color. This corresponds to a comparatively good and satisfactory saturation.

According to another further embodiment, in the phosphor mixture, a mixing ratio between the first phosphor and the second phosphor is between 75:25 and 55:45.

This ratio ensures stability of the chromaticity coordinate and the luminous flux against scattering and fluctuations.

According to another further embodiment, the phosphor composition may be provided as a platelet formed from crystals pressed in a ceramic matrix or as particles embedded in a silicone layer and sedimented therein.

According to another further development of the embodiment example, the first phosphor can be composed of particles which correspond, for example, to a phosphor marketed under the trade name QL916 in the group of companies of the applicant, and/or the second phosphor is composed of particles which correspond, for example, to a phosphor marketed under the trade name QL906 in the group of companies of the applicant. Both phosphors belong to the class of europium-activated strontium-calcium-alumonitride silicates or those with the chemical short formula Sr(Sr,Ca)Si2Al2N6:Eu2+. The two phosphors differ in their structural parameters, allowing different hues to be achieved in conversion. For example, the QL916 phosphor emits more in the garnet red range, while the QL906 phosphor tends more toward the purple red. Europium-activated strontium calcium alumonitride silicates were recently described in Bichler, D.: “Narrow-Band Emitting Red Phosphor Sr(Sr,Ca)Si2Al2N6:Eu2+”, abstract of oral presentation, [10.1002/zaac.201604017], Z. Anorg. Allg. Chem. 2016, p. 1012, Wiley-VCH Verlag GmbH & Co. KGaA, Weinheim. Their advantage especially also for the present application is the narrow band emission.

According to a further aspect, the phosphor mixture according to any of the above embodiments is provided in combination with a semiconductor light source, wherein the semiconductor light source may be configured to emit light in a wavelength range between 380 nm and 480 nm, and wherein the phosphor mixture is coated on a light emitting surface of the semiconductor light source.

### BRIEF DESCRIPTION OF THE DRAWINGS

Further advantages, advantageous embodiments and further developments will become apparent from the non-limiting embodiments described below in connection with the figures.

FIG. 1 depicts a schematic representation of the CIE standard color chart (CIE 1931), with the ECE-compliant area for red brake lights, taillights and rear fog lights (ECE Regulation 48) entered at the bottom right;

FIG. 2 depicts an enlarged section of the CIE standard color chart from FIG. 1 with measured color locations for a first phosphor (viewed individually), for a second phosphor (viewed individually) and for a phosphor mixture of the two phosphors for different layer thicknesses of the conversion layer in question;

FIG. 3 depicts the behavior in the cx direction for the first phosphor (QL916), the second phosphor (QL906) and for the phosphor mixture of both (in a ratio of 70:30) as a function of the dispensing quantity M used to build up the conversion layer, whereby scatter in the measured values was also taken into account in each case;

FIG. 4 is similar to FIG. 3, but for the behavior in cy direction;

FIG. 5 depicts the dependence of the photometric luminous flux Φᵥ on the dispensing amount M for a first phosphor (QL916), a second phosphor (QL906) and for the phosphor mixture of both (in the ratio 70:30);

FIG. 6 depicts the correlation of luminous flux Φᵥ with temperature T for the first phosphor (QL916), the second phosphor (QL906), and for the phosphor mixture of both (in the ratio 70:30);

FIG. 7 depicts a measurement series of the chromaticity coordinates in the CIE standard chromaticity diagram for different temperatures T. For the first phosphor (QL 916), the second phosphor (QL 906) and the phosphor mixture, measurement series are shown for different dispensing amounts M of 6.5 mg and for a dispensing amount M of 7.0 mg, respectively;

FIG. 8 depicts the recorded spectra of the pure substances (first phosphor: Bz. 230, and second phosphor: Bz. 240) in comparison with each other (photometric luminous flux Φᵥ plotted against wavelength λ), with the actual spectrum convolved with the eye sensitivity;

FIG. 9 is similar to FIG. 8, but in an integrated representation.

In the non-limiting embodiments and figures, identical elements, elements of the same kind or elements having the same effect may each be provided with the same reference signs. The elements shown and their proportions to one another are not necessarily to be regarded as true to scale; rather, individual elements may be shown exaggeratedly large for better representability and/or better understanding.

### DETAILED DESCRIPTION

In the following description, it should be appreciated that the present disclosure of the various aspects is not limited to the details of the structure and arrangement of the components as shown in the following description and figures. The embodiments may be put into practice or carried out in various ways. It should further be appreciated that the expressions and terminology used herein are used for the purpose of specific description only, and these should not be construed as such in a limiting manner by those skilled in the art.

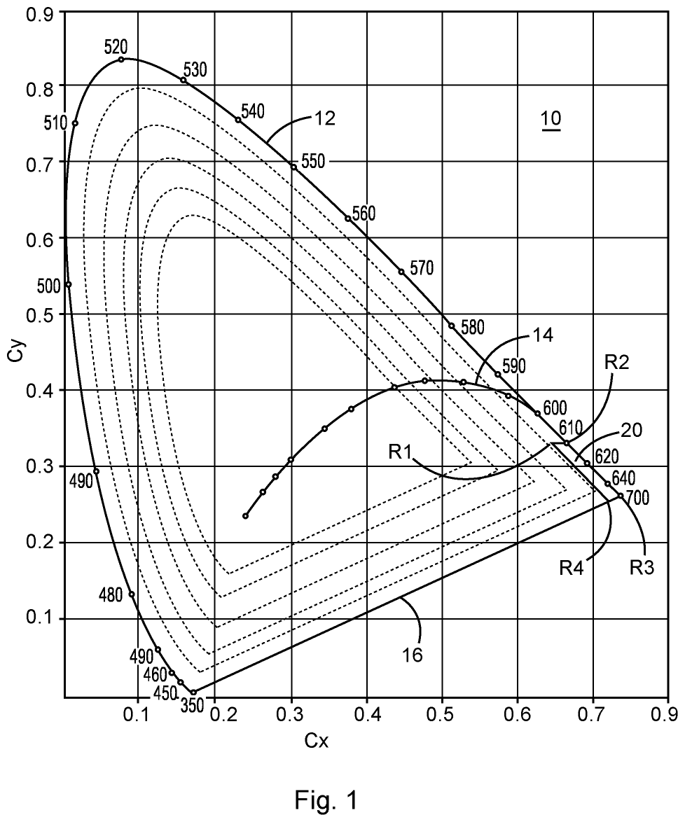

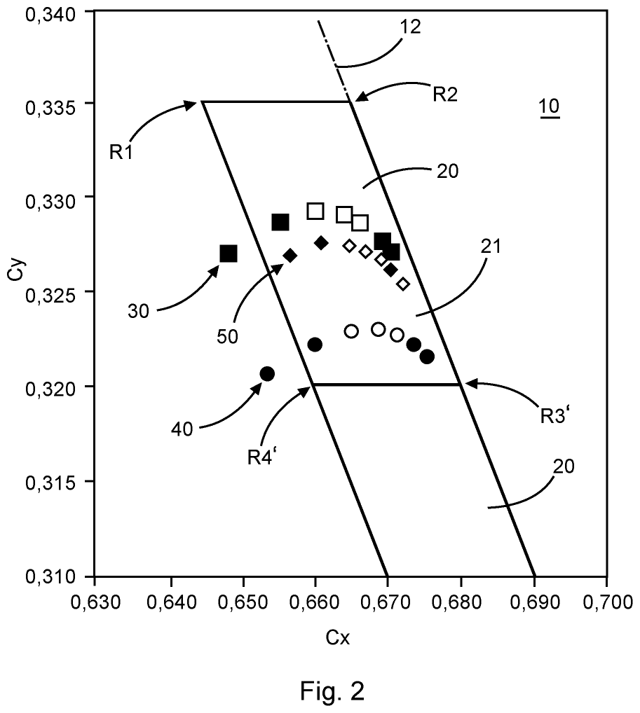

A non-limiting embodiment is described with reference to FIGS. 1 to 2. FIG. 1 shows in schematic representation the graphical reproduction of the general CIE standard color chart 10 (CIE 1931, 2° field of view), with an ECE-compliant area 20 for red brake lights, tail lights and rear fog lights (ECE regulation 48) entered at the bottom right. On the abscissa (x-axis), the proportion between 0 and 1 of the basic color red (700 nm) is plotted as cx, while the ordinate (y-axis) represents with cy the proportion between 0 and 1 of the basic color green (546.1 nm). The third dimension of this diagram, which points out of the drawing plane, is not shown and represents the value cz between 0 and 1, which reflects the proportion of the primary color blue (435.8 nm). With these 3 primary colors, all colors visually detectable by the human eye can be assigned to exactly one proportion combination in superposition. The cx-cy plane in the diagram represents a kind of projection plane from three-dimensional space.

The horseshoe-shaped outer edge represents the spectral color line 12 with spectral colors from red to yellow and from green to blue. These correspond to monochromatic light emission at the wavelengths shown in FIG. 1. The spectral colors correspond to ultra-pure colors with full saturation. The horseshoe is bounded at the bottom by the so-called purple line 16, which is drawn linearly from a point corresponding to the color blue at 380 nm to a point corresponding to the color red at 700 nm. Towards the center of the diagram, there are color mixtures that extend from unsaturated hues on the outside to white hues on the very inside. Also entered for purely illustrative purposes is a line 14 resulting for black bodies of different temperatures, with temperatures entered as examples in each case.

According to ECE Regulation 48, red light is mandatory for brake lights, tail lights, rear fog lights, etc., on vehicles. For the purpose of clear differentiation from yellow light (e.g. turn signals) or white light (e.g. low beam), the CIE standard chromaticity diagram specifies an area 20 covering red light that extends (in FIG. 1, bottom right) along a range of red spectral colors (from garnet to deep or purple) with comparatively high saturation. The degree of saturation corresponds to a distance of a chromaticity point in the CIE chromaticity diagram from a nearest spectral color. The corresponding direction is nearly parallel to the cx-axis (i.e., the red component). The area is defined by four corner positions R=(cx; cy), define a very narrow, square, almost parallelogram-like strip. The four corner positions are given by:
R1=(0,645; 0,335),
R2=(0,665; 0,335),
R3=(0.735; 0.265), and
R4=(0,721; 0,259).

In FIG. 2, an enlarged section of the CIE standard color chart of FIG. 1 is shown with measured color locations for a first phosphor (viewed individually), for a second phosphor (viewed individually) and for a phosphor mixture of the two phosphors for different layer thicknesses of the conversion layer in question. The area 20 is shown only with respect to its upper part, wherein a sub-area 21 with corner positions R1, R2, R3′ and R4′ is defined, denoted “dry red”, and is a working area for the present embodiment. The lower corner positions R3′=(0.680; 0.320) and R4′=(0.660; 0320), which define the lower limit of this “dry red”, are significantly higher than the corner positions R3 and R4. The area below the exposures R3′ and R4′ is therefore less relevant, because here the physical emission spectrum is already very strongly affected by a convolution with the sensitivity curve of the human eye.

The phosphor mixture is composed of a first phosphor of the type QL916, manufactured and distributed in the group of companies of the applicant and a second phosphor of the type QL906, also manufactured and distributed in the group of companies of the applicant. As described at the beginning, these are from the class of europium-activated strontium-calcium-alumonitride silicates or those with the chemical abbreviation Sr(Sr,Ca)Si2Al2N6:Eu2+, which have been known as such since 2016 at the latest (for reference see above). They differ in structural parameters such as particle sizes or element ratios, so that the color locations of the two phosphors achieved in emission in the CIE standard chromaticity diagram have a vertical difference in the cy direction (green component) of more than 0.005 (for the same conversion factor) (see FIG. 2). In the embodiment example, they are mixed in a mass ratio of 70:30. The semiconductor light source used is an LED chip with a 1 mm² light-emitting surface, which, when supplied with power, emits blue light in a wavelength range from 447.5 nm to 450 nm. A conversion layer containing the phosphor mixture is formed on the light-emitting surface. A median value of the particle sizes D50 in both phosphors is between 5 μm and 20 μm. For production, the particles of the two phosphors are mixed and embedded in liquid silicone. In this, the particles are sedimented and the silicone hardens. The thickness of the silicone layer is 200 to 300 μm, but the backfill height of the phosphor particles after sedimentation is only between 30 and 70 μm including the limits. This is the effective thickness of the conversion layer considered here. Finally, the conversion layers are cut out of the silicone layer in a suitable size and glued onto the light-emitting surface of the semiconductor light sources.

The backfill height or the thickness of the conversion layer determines the degree of conversion of the light scattered from the semiconductor light source into the phosphor mixture (from blue to red). The thicker the conversion layer, the stronger the conversion. In the series of measurements shown in FIG. 2, however, it is not the thickness of the conversion layer that is indicated, but rather the corresponding dispensing weight (in milligrams mg), which reflects the mass of the phosphor added to the silicone and sedimented there, whereby this here refers to an entire panel with several semiconductor light sources.

FIG. 2 shows the results for the first phosphor and the second phosphor for the case in which they are present alone, i.e. not as a mixture, in a conversion layer. Series of measurements were taken for dispensing weights of 6.0 mg, 6.5 mg, 7.0 mg, 7.5 mg, 8.0 mg, 8.5 mg, 9.0 mg and 9.5 mg, i.e. 7 measured values each. The color locus for the light from the semiconductor light source with the first or second phosphor at a dispensing weight of 6.0 mg is on the left side in the CIE standard chromaticity diagram, i.e., at lower value cx, i.e., at low color saturation, because conversion is still lowest here and a considerable proportion of the blue light emitted by the semiconductor light source contributes to the spectrum. For higher dispensing weights in each case, the respective color locations for each phosphor follow one after the other towards higher values of cx.

The first phosphor is a phosphor already used for brake, tail and rear fog lamps and emits in the garnet color range. In FIG. 2, the measurement series (chromaticity coordinates 30 for the first phosphor) is represented by squares. As can be seen, at a low dispensing weight of 6.0 mg, the color location of the combined emission from the semiconductor light source and the first phosphor lies outside the ECE-compliant area 20 or 21 for red light in vehicle lighting. Only from 6.5 mg dispensing weight is the conversion sufficient to achieve just adequate saturation.

The same applies to the second phosphor, whose emission is already in the deep purple range and which is subject to greater fluctuations in luminous flux as the temperature varies, which is why this phosphor is intrinsically less suitable for use in generating red light in vehicle lamps. In FIG. 2, the corresponding series of measurements (chromaticity coordinates 40 for the first phosphor) is represented by circles. Here, too, the chromaticity coordinates of the combined emission from the semiconductor light source and the second phosphor are outside the ECE-compliant range at a low dispensing weight of 6.0 mg, and sufficient color saturation is obtained only from a dispensing weight of 6.5 mg.

The corresponding results of the measurement series (color locations 50) for the phosphor mixture of the embodiment are shown as diamonds in FIG. 2. The series begins on the left with the color location for the light emission from the combination of semiconductor light source and phosphor mixture with a dispensing weight of 6.0 mg. Here it is already remarkable that the first measuring point lies within area 20 for an ECE-compliant red light. If the two corresponding points of the measurement series for the first phosphor (square lying furthest to the left in FIG. 2) and the second phosphor (circle lying furthest to the left) are connected by a line, the corresponding point (color location) for the phosphor mixture (diamond lying furthest to the left) lies very clearly to the right of the line, i.e. in an area of significantly improved saturation compared with both phosphors considered individually. Conventionally expected for simple color mixing, a color locus would be approximately at (cx=0.65; cy=0.325) when considering the 70:30 mixing ratio. However, these observations continue slowly weakening for higher dispensing weights. However, it can be seen that from about 8.0 mg dispensing weight, full conversion seems to occur in all 3 cases (phosphors individually irradiated and phosphor mixture) and hardly any improvements in color saturation are achieved. Here, the three color locations lie on one line, so that simple color mixing is present in a ratio of 70:30 (see the points farthest to the right of the 3 measurement series, corresponding to 9.5 mg dispensing weight.

In summary, however, it can be stated that the color locations are much closer together in the phosphor mixture, so that noticeable color fluctuations (degree of saturation) during operation and between different batches are significantly reduced, and that color saturations in the permissible range are obtained even at lower dispensing weights.

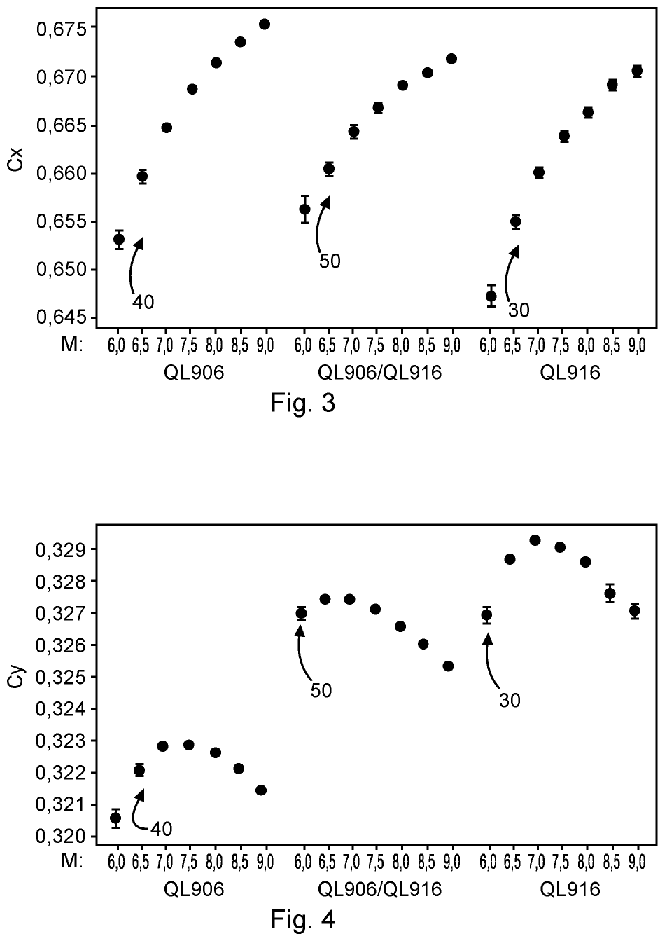

FIGS. 3 to 9 illustrate the findings on the basis of measurements carried out in the embodiment. FIGS. 3 and 4 show the behavior in cx and cy for the first phosphor (QL916), the second phosphor (QL906, considered individually in each case) and for the phosphor mixture of both (in the ratio 70:30) as a function of the dispensing quantity M used to build up the conversion layer, whereby, in contrast to FIG. 2, scatter in the measured values was also taken into account in each case.

It can be seen that, with regard to the red component cx of the emitted and transmitted light, the color locations 50 are significantly closer together in the case of the phosphor mixture starting at a dispensing amount of 6.0 mg up to 9.0 mg than is the case with the color locations 30 of the first phosphor and 40 of the second phosphor. Also, the dispersion obtained in the phosphor mixture remains comparable to the individual phosphors considered individually.

With regard to the cy direction (green component of the emitted and transmitted light), a flattening of the curve in the case of the phosphor mixture already occurs between 6.7 and 7.0 mg. This means that an invariance of the green component can already be achieved here at considerably lower dispensing quantities M than in the case of the individual phosphors. Furthermore, the curve is flatter overall. Thus, the desired red component can be effectively achieved with less effect on the green component, even with lower layer thicknesses of the conversion layer. In the embodiment example, the dispensing amount corresponds to a thickness of 30 μm to 70 μm, with a median value of the particle size D50 in the phosphor mixture of between 5 μm and 20 μm.

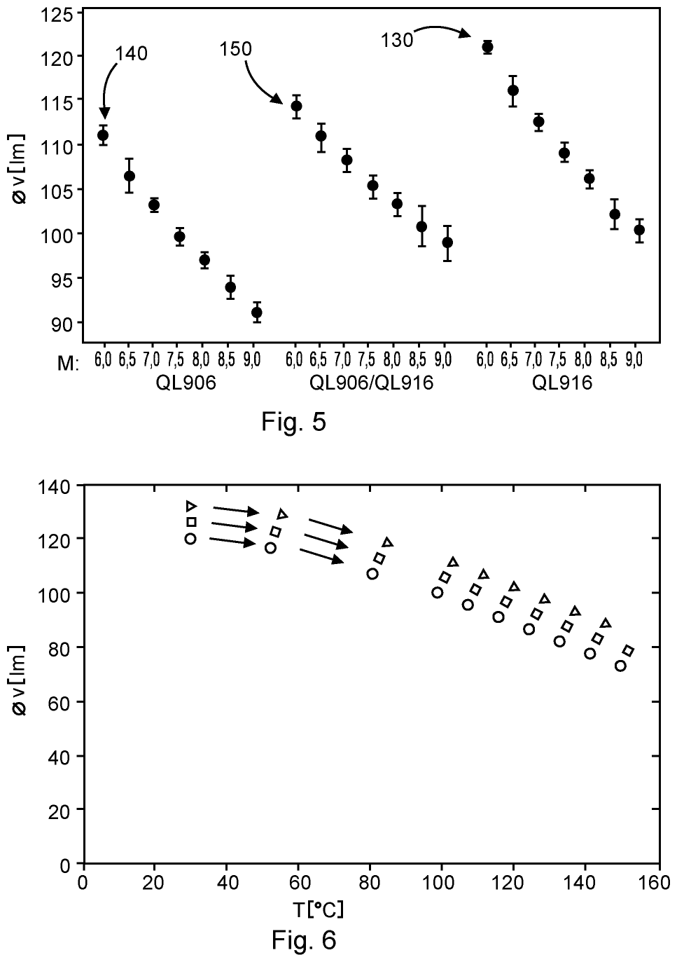

FIG. 5 shows the dependence of the photometric luminous flux Φᵥ on the dispensing quantity M for the first phosphor (QL916), the second phosphor (QL906, considered individually in each case) and for the phosphor mixture of both (in the ratio 70:30). It can be seen that the scatter of the measured values of series 150 for the phosphor mixture with e.g. 6.5 mg is comparable to the fluctuations for the pure substances, i.e. the measured values 130 for the first phosphor and 140 for the second phosphor (each considered individually), but the luminous flux is not reproduced in the ratio 70:30. The corresponding measured value of row 150 is 111 lm, but at the specified ratio it should be closer to the value of the first phosphor (about 117 lm) than to the value of the second phosphor (about 107 lm). This means a slight loss of luminous flux, but this is acceptable, especially since FIG. 5 shows that the interval of luminous fluxes for dispensing amounts between 6.0 mg and 9.0 mg is smallest for the phosphor mixture.

FIG. 6 shows a correlation of the luminous flux Φᵥ with the temperature T for the first phosphor (QL916), the second phosphor (QL906, each considered individually) and for the phosphor mixture of both (in the ratio 70:30). It can be seen that in all cases the luminous flux drops toward higher temperatures, with the effect as described being most noticeable for the second phosphor (luminous flux measurement series 140, indicated by circles in FIG. 6). The luminous flux measurement series 130 of the garnet-colored first phosphor remains comparatively the most stable, while the luminous flux measurement series 150 for the phosphor mixture lies in between, but is also closer to that of the purple-colored second phosphor.

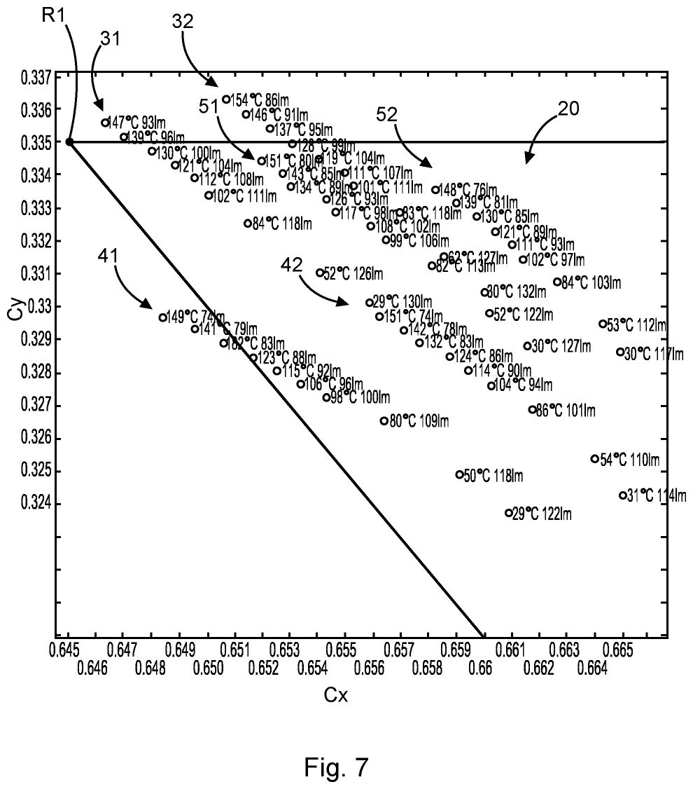

The respective series of measurements of the color locations in the CIE standard chromaticity diagram are shown for different temperatures T in FIG. 7. For the first phosphor, the second phosphor and the phosphor mixture, measurement series are shown respectively for a dispensing amount M of 6.5 mg (measurement series 31: first phosphor, 41: second phosphor, 51: phosphor mixture) and for a dispensing amount M of 7.0 mg (measurement series 32: first phosphor, 42: second phosphor, 52: phosphor mixture). These are the potential dispensing amounts for the phosphor mixture as shown above. It can be seen that the “gain” in cy and cx (i.e., a higher degree of saturation) of the phosphor mixture is maintained even at higher temperatures. Only the luminous flux (1)v, as described, is lower than that of the pure phosphor QL916 as the first phosphor, but this is acceptable in view of the enormous advantages obtained with the phosphor mixture. In addition, as can be seen in FIG. 7, not only for all relevant dispensing quantities but also for all possibly occurring temperatures T, the color locations are safely located within the ECE-compliant area 20, which is defined by corner positions R=(cx; cy), which are given by
R1=(0,645; 0,335),
R2=(0,665; 0,335),
R3=(0.735; 0.265), and
R4=(0,721; 0,259).

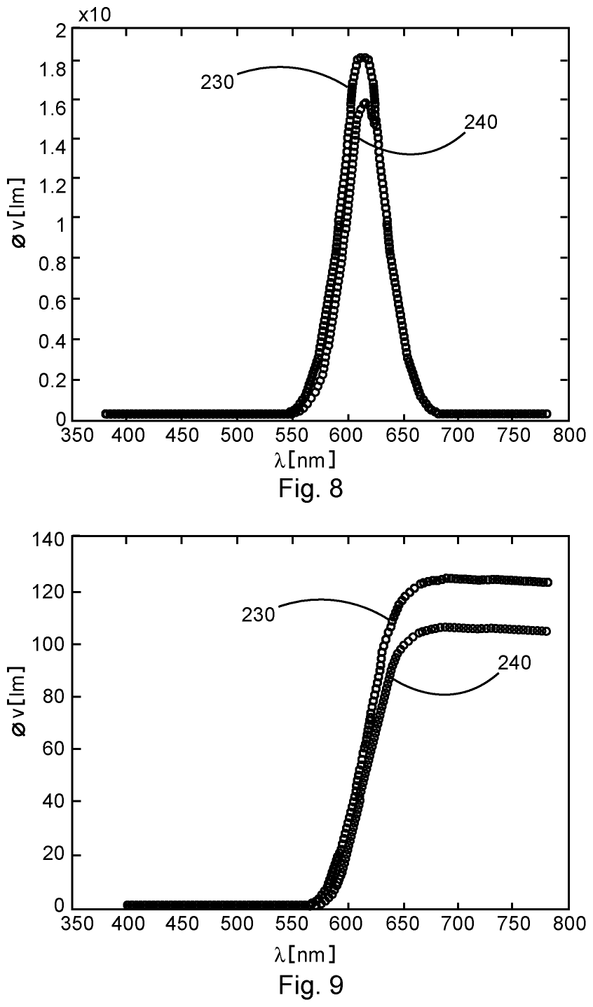

FIGS. 8 and 9 serve to explain the filter effect that is exploited here. Shown are the recorded spectra of the pure substances (first phosphor: reference 230, and second phosphor: reference 240) compared to each other (photometric luminous flux Φᵥ plotted against wavelength λ), with the actual spectrum convolved with eye sensitivity. It can be seen that the first phosphor (QL916) produces its greater luminous flux in a range of 500-700 nm or more narrowly 550-650 nm. This range also includes the major portion of the light emitted by the second phosphor (QL906), but with the difference that the second phosphor emits hardly any light in a region of the first wavelength range between 500 and 580 nm, i.e., the short-wave flank of the spectrum of the light emitted by the first phosphor. FIG. 9 shows the integrated luminous flux from FIG. 8 in a different illustration to make the difference more visible. Instead of emitting light, the second phosphor absorbs or filters light and reemits it in its emission range above 600 nm. The spectrum thus becomes narrower, the degree of color saturation increases, and the chromaticity coordinate is shifted toward the red.

It should be noted that the described combination of phosphors is only one of many possibilities, and that the skilled person can also combine other individual phosphors using the described idea to achieve the same effect. It is also possible to combine more than two phosphors. Furthermore, it is also possible to combine phosphors according to the instructions given in the appended claims, which are in no way subject to the loss of luminous flux described in the embodiments and are nevertheless comprised. Furthermore, it is also possible to combine phosphors according to further embodiment examples in which the filtering effect of the phosphor that is weaker in light and subject to greater fluctuations is not so clearly evident.

1. A phosphor mixture configured for a conversion layer coated on a semiconductor light source, wherein the phosphor mixture comprises:
a first phosphor adapted to emit light of a first unsaturated color when irradiated with light from the semiconductor light source and when provided as the only phosphor in the conversion layer, wherein the first unsaturated color is associated with a first position in a CIE chromaticity diagram adjacent to and above a position of a selected target color of the phosphor composition in the CIE chromaticity diagram;
a second phosphor adapted to emit light of a second unsaturated color when irradiated with light from the semiconductor light source and when provided as the only phosphor in the conversion layer, the second unsaturated color being associated with a second position in a CIE chromaticity diagram adjacent to and below the position of the selected target color of the phosphor composition in the CIE chromaticity diagram; and
wherein the position of the selected target color of the phosphor composition in the CIE chromaticity diagram is in an area defined by corner positions R=(cx; cy) given by
R1=(0,645; 0,335),
R2=(0,665; 0,335),
R3=(0.735; 0.265), and
R4=(0,721; 0,259).

2. The phosphor mixture according to claim 1, wherein
the phosphor mixture is adapted to emit light of the selected target color associated with the position in the CIE chromaticity diagram when irradiated with light from the semiconductor light source and provided in the conversion layer, the position having a degree of saturation represented by a distance from a closest spectral color greater than a corresponding degree of saturation of the first unsaturated color and the second unsaturated color.

3. The phosphor mixture according to claim 1, wherein:
the first phosphor is adapted, when irradiated with light by the semiconductor light source, to emit light having a first spectrum exhibiting light emission in a first wavelength range;
said second phosphor is adapted, when irradiated with light by said semiconductor light source, to emit light having a second spectrum exhibiting light emission in a second wavelength range, said second wavelength range being different from said first wavelength range;
wherein the first wavelength region overlaps the second wavelength region at least in an interval ranging from about 600 nm to about 700 nm.

4. The phosphor mixture according to claim 3, wherein
maximum values of the first and second spectra are each at wavelengths; independently, ranging from 600 nm to 700 nm.

5. The phosphor mixture according to claim 3, wherein
the second phosphor is adapted to absorb and filter light in a portion of the first wavelength range that extends adjacent to the lower limit thereof.

6. The phosphor mixture according to claim 5, wherein
the second phosphor is adapted to absorb and filter light in an interval of the first wavelength ranging from about 500 to about 580 nm.

7. The phosphor mixture according to claim 1, wherein
the semiconductor light source is configured to emit blue light.

8. The phosphor mixture according to claim 7, wherein
the semiconductor light source is configured to emit light in a wavelength ranging from 447.5 nm to 450 nm.

9. The phosphor mixture according to claim 7, wherein:
a thickness of the phosphor mixture ranges from 30 μm to 70 μm; and a median value of the particle size D50 in the phosphor mixture ranges from 5 μm to 20 μm.

10. The phosphor mixture according to claim 9, wherein
the second phosphor, when provided as a single phosphor in the conversion layer and irradiated by the semiconductor light source, is adapted to emit light of a second unsaturated color associated with a position in a CIE standard chromaticity diagram having a basic color component of green of cy≤0.324.

11. The phosphor mixture according to claim 9, wherein
the first phosphor, when provided as a single phosphor in a conversion layer and irradiated by the semiconductor light source, is adapted to emit light of a first unsaturated color associated with a position in a CIE standard chromaticity diagram having a fundamental color component of green of cy≥0.328.

12. The phosphor mixture according to claim 9, wherein
the phosphor mixture is configured, when irradiated by the semiconductor light source, to emit light of the selected target color associated with a position in the CIE chromaticity diagram corresponding to a saturation level represented by a distance≤0.012 in the cx direction from the nearest spectral color.

13. The phosphor mixture according to claim 1, wherein
a mixing ratio in the mixture between the first phosphor and the second phosphor ranges from 75:25 to 55:45.

14. The phosphor mixture according to claim 1, wherein
the phosphor composition is configured as a platelet formed from crystals pressed in a ceramic matrix or configured as particles embedded in a silicone layer and demoulded therein.

15. The phosphor mixture according to claim 1, wherein each of the first phosphor and the second phosphor comprises particles corresponding to phosphors from the class of europium-activated strontium calcium alumonitride silicates.

16. A semiconductor light source comprising the phosphor mixture according to claim 1, wherein the semiconductor light source is adapted to emit light in a wavelength ranging from 380 nm to 480 nm, and wherein the phosphor mixture is coated on a light emitting surface of the semiconductor light source.

17. A vehicle lamp comprising the semiconductor light source according to claim 16.

18. The vehicle lamp of claim 17, wherein the vehicle lamp is adapted to be mounted in a brake light, tail light, or rear fog light lighting device.
